(19) United States
(12) Patent Application Publication
(10) Pub. No.: US 2023/0317659 A1
(43) Pub. Date: Oct. 5, 2023

(54) METHOD FOR REPLACING SOLDER BALLS OF AN ELECTRONIC PACKAGE

(71) Applicant: SKYWORKS SOLUTIONS, INC., Irvine, CA (US)

(72) Inventors: Marco Antonio Carmona, Corona, CA (US); Matthew Sean Read, Canyon Lake, CA (US)

(21) Appl. No.: 18/124,154

(22) Filed: Mar. 21, 2023

Related U.S. Application Data
(60) Provisional application No. 63/362,065, filed on Mar. 29, 2022.
(60) Provisional application No. 63/362,069, filed on Mar. 29, 2022.
(60) Provisional application No. 63/362,064, filed on Mar. 29, 2022.

(51) Int. Cl. H01L 23/00

(52) U.S. Cl. CPC H01L 24/11; H01L 2224/11849; H01L 2224/1147

(57) ABSTRACT

A method for replacement of solder balls of an electronic package soldered to seats located on a surface of the electronic package. The method comprises collectively heating the solder balls to melt the solder balls, removing each one of the solder balls from the corresponding seats by suction, providing a plurality of replacement solder balls, for each seat, positioning a corresponding one of the replacement solder balls on the respective seat to form an array of seated replacement solder balls, and collectively heating the array of seated replacement solder balls such that the replacement solder balls reflow and form metallurgical bonds with the seats. A system for replacing solder balls of an electronic package is also provided. An assembly for use in locating a plurality of solder balls onto an array of seats of an electronic package is also provided.

### CROSS-REFERENCE TO RELATED APPLICATIONS

This application claims priority under 35 U.S.C. § 119(e) to U.S. Provisional Patent Application Ser. No. 63/362,065, titled “REPLACING SOLDER BALLS OF AN ELECTRONIC PACKAGE,” filed Mar. 29, 2022, to U.S. Provisional Patent Application Ser. No. 63/362,069, titled “REPLACING SOLDER BALLS OF AN ELECTRONIC PACKAGE,” filed Mar. 29, 2022, and to U.S. Provisional Patent Application Ser. No. 63/362,064, titled “REPLACING SOLDER BALLS OF AN ELECTRONIC PACKAGE,” filed Mar. 29, 2022, the subject matter of each being incorporated herein in its entirety by reference for all purposes.

### BACKGROUND

### Field

The present disclosure relates to a method for replacing solder balls of an electronic package. The present disclosure also relates to a system for replacing solder balls of an electronic package. The present disclosure also relates to an assembly for use in locating a plurality of solder balls onto an array of seats of an electronic package.

### Description of the Related Technology

Conventional electronic packages have a substrate with one or more electronic components or modules mounted on at least one surface of the substrate. An array of solder balls is typically provided on a surface of the electronic package to enable the package to be mounted to the surface of a circuit board. Flaws associated with the solder balls may render the electronic package unsuitable for its intended use.

### SUMMARY

According to one embodiment there is provided a method for replacing solder balls of an electronic package, the electronic package comprising an array of solder balls soldered to a corresponding array of seats located on a surface of the electronic package. The method comprises collectively heating the array of solder balls to melt the solder balls, removing each one of the array of solder balls from the corresponding seat by application of suction to the respective melted solder ball, providing a plurality of replacement solder balls, for each seat of the array of seats, positioning a corresponding one of the replacement solder balls on the respective seat to form an array of seated replacement solder balls, and collectively heating the array of seated replacement solder balls such that the replacement solder balls reflow and form a metallurgical bond with the seats.

In one example the step of collectively heating the array of solder balls is preceded by a preliminary heating step, the preliminary heating step comprising baking the electronic package for a predetermined minimum time period at a temperature of at least 110 degrees Celsius, or at least 115 degrees Celsius, or at least 120 degrees Celsius, or at least 125 degrees Celsius.

In one example the predetermined minimum time period is 3.5 hours, or 4 hours, or 4.5 hours.

In one example the step of collectively heating the array of solder balls to melt the solder balls is preceded by a step of applying a fluxing agent to the electronic package such that the fluxing agent covers the solder balls.

In one example the step of applying the fluxing agent to the electronic package comprises confining application of the fluxing agent to cover the solder balls and portions of the electronic package separating adjacent ones of the solder balls.

In one example the step of applying the fluxing agent to the electronic package comprises applying the fluxing agent to the electronic package so as to form a continuous path of the fluxing agent covering each of the solder balls.

In one example the fluxing agent is water soluble.

In one example the step of applying the fluxing agent to the electronic package comprises dispensing the fluxing agent through a hollow needle coupled to a reservoir of the fluxing agent.

In one example the step of applying the fluxing agent to the electronic package is preceded by a purging step, the purging step comprising purging the hollow needle of air.

In one example the purging step comprises purging the hollow needle of air such that fluxing agent dispensed from the hollow needle is free of air bubbles.

In one example the method further comprises dispensing additional fluxing agent to either or both of the solder balls and portions of the electronic package separating adjacent ones of the solder balls during either or both of the steps of collectively heating the array of solder balls to melt the solder balls, or removing each one of the array of solder balls from the corresponding seat by application of suction to the respective melted solder ball.

In one example the step of collectively heating the array of solder balls to melt the solder balls comprises mounting the electronic package to a first heater assembly.

In one example the first heater assembly comprises a hot plate assembly.

In one example mounting the electronic package to the first heater assembly comprises providing a clamping assembly, using the clamping assembly to clamp the electronic package in a predetermined orientation, and mounting the clamping assembly to the first heater assembly.

In one example mounting the clamping assembly to the first heater assembly retains the electronic package in the predetermined orientation.

In one example the predetermined orientation is an orientation in which the array of solder balls are exposed in line of sight.

In one example the step of collectively heating the array of solder balls to melt the solder balls comprises heating the first heater assembly to a predetermined temperature.

In one example the predetermined temperature exceeds a melting temperature of the solder balls by a temperature differential of between 10° C. and 40° C., or between 10° C. and 30° C., or between 10° C. and 20° C.

In one example the first heater assembly is pre-heated to the predetermined temperature prior to the electronic package being mounted to the first heater assembly.

In one example the method further comprises maintaining the first heater assembly at the predetermined temperature over the step of collectively heating the array of solder balls to melt the solder balls.

In one example the step of removing each one of the array of solder balls from the corresponding seat by application of suction to the respective melted solder ball is performed while the electronic package is mounted to the first heater assembly.

In one example the step of removing each one of the array of solder balls from the corresponding seat by application of suction to the respective melted solder ball comprises providing a hollow needle coupled to a suction source, and positioning the hollow needle over the melted solder ball such that the suction source applies suction via the hollow needle to suck the melted solder ball through the hollow needle.

In one example the step of removing each one of the array of solder balls from the corresponding seat by application of suction to the respective melted solder ball further comprises heating the needle.

In one example heating the needle comprises heating the needle to at least the melting temperature of the solder balls.

In one example the step of removing each one of the array of solder balls from the corresponding seat by application of suction to the respective melted solder ball comprises successively removing each of the melted solder balls in turn.

In one example the step of removing each one of the array of solder balls from the corresponding seat is followed by a step of applying a cleaning agent to the electronic package.

In one example the cleaning agent comprises isopropyl alcohol.

In one example the step of positioning the corresponding one of the replacement solder balls on the respective seat is preceded by a step of applying a fluxing agent to the array of seats of the electronic package such that the fluxing agent does not bridge adjacent ones of the seats.

In one example the step of applying the fluxing agent to the array of seats comprises dispensing the fluxing agent through a hollow needle coupled to a reservoir of the fluxing agent.

In one example the step of applying the fluxing agent to the array of seats is preceded by a purging step, the purging step comprising purging the hollow needle of air.

In one example the purging step comprises purging the hollow needle of air such that fluxing agent dispensed from the needle is free of air bubbles.

In one example the step of positioning the corresponding one of the replacement solder balls on the respective seat to form an array of seated replacement solder balls comprises providing a mask, the mask comprising an array of apertures arranged to correspond to the array of seats, positioning the mask over the electronic package such that the array of apertures are aligned with the array of seats, and disposing one of the plurality of replacement solder balls in a corresponding one of the array of apertures such that the replacement solder ball is located on a corresponding one of the array of seats.

In one example disposing one of the plurality of replacement solder balls in the corresponding one of the array of apertures is repeated until each of the array of apertures has received a corresponding one of the plurality of replacement solder balls.

In one example each one of the array of apertures is sized to receive only a single one of the plurality of replacement solder balls.

In one example the plurality of replacement solder balls each have a diameter in a range of 220 micrometers to 280 micrometers.

In one example the mask comprises a perimeter wall substantially surrounding the array of apertures, and disposing one of the plurality of replacement solder balls in a corresponding one of the array of apertures comprises disposing the plurality of replacement solder balls on a surface of the mask inwards of the perimeter wall and inclining the mask such that the plurality of replacement solder balls roll over the surface of the mask until each one of the array of apertures receives a corresponding one of the plurality of replacement solder balls, the perimeter wall substantially confining the plurality of replacement solder balls to inwards of the perimeter wall.

In one example the method further comprises inclining the mask to pour excess ones of the plurality of replacement solder balls from the surface of the mask through an opening defined in the perimeter wall.

In one example the step of collectively heating the array of replacement solder balls is followed by a step of applying a cleaning agent to the electronic package.

In one example the cleaning agent comprises isopropyl alcohol.

According to another embodiment there is provided a system for replacing solder balls of an electronic package, the electronic package comprising an array of solder balls soldered to a corresponding array of seats located on a surface of the electronic package. The system comprises a first heater assembly configured to receive the electronic package and collectively heat the array of solder balls to melt the solder balls, a solder removal tool configured to apply suction to each one of the melted solder balls to thereby remove the melted solder ball from the corresponding seat, a mask comprising an array of apertures arranged to correspond to the array of seats, the mask configured to be positioned over the electronic package such that the array of apertures are aligned with the array of seats, each one of the array of apertures configured to receive a respective replacement solder ball and thereby locate the replacement solder ball on a corresponding one of the array of seats, and a second heater assembly configured to receive the electronic package and collectively heat and reflow the replacement solder balls to form a metallurgical bond with the seats.

In one example the system further comprises an oven, the oven configured to bake the electronic package in a preliminary heating step for a predetermined minimum time period at a temperature of at least 110 degrees Celsius, or at least 115 degrees Celsius, or at least 120 degrees Celsius, or at least 125 degrees Celsius.

In one example the predetermined minimum time period is 3.5 hours, or 4 hours, or 4.5 hours.

In one example the system further comprises a fluxing assembly, the fluxing assembly comprising a reservoir of a fluxing agent, the fluxing assembly configured to selectively apply the fluxing agent to the electronic package.

In one example the fluxing agent is water soluble.

In one example the fluxing assembly further comprises a hollow needle, the hollow needle coupled to the reservoir of the fluxing agent.

In one example the hollow needle has an arcuate profile and is crimp-free over a length of the hollow needle.

In one example the hollow needle extends between a base and a tip, the base coupled to the reservoir of the fluxing agent, a tangent to the tip of the hollow needle deviating from a tangent to the base of the hollow needle by an acute angle, the acute angle having a value in a range of between 15 degrees and 45 degrees, or between 25 degrees and 45 degrees, or between 35 degrees and 45 degrees.

In one example the fluxing assembly is configured to detachably receive a cartridge, the cartridge comprising the reservoir of the fluxing agent.

In one example the first heater assembly comprises a hot plate assembly.

In one example the first heater assembly is configured to be heated to a predetermined temperature.

In one example the predetermined temperature is at least 250° C., or at least 260° C., or at least 270° C., or at least 280° C., or at least 290° C., or at least 300° C.

In one example the system further comprises a clamping assembly configured to clamp the electronic package in a predetermined orientation, the clamping assembly further configured to be mounted to the first heater assembly.

In one example the clamping assembly is configured to be locked in position relative to the first heater assembly when mounted to the first heater assembly.

In one example the clamping assembly comprises an outer clamping element and an inner clamping element, the outer clamping element arranged to substantially surround the inner clamping element.

In one example one or both of the outer and inner clamping elements are slidably moveable relative to each other to clamping the electronic package between opposing faces of the outer and inner clamping elements.

In one example the solder removal tool comprises a hollow needle coupled to a suction source so as to generate suction at a tip of the needle in use.

In one example the solder removal tool is configured to selectively trigger the generation of suction at the tip of the needle.

In one example the solder removal tool is further configured to heat the hollow needle in use.

In one example the hollow needle has an arcuate profile and is crimp-free over a length of the hollow needle.

In one example the hollow needle extends between a base and the tip, a tangent to the tip of the hollow needle deviating from a tangent to the base of the hollow needle by an acute angle, the acute angle having a value in a range of between 15 degrees and 45 degrees, or between 25 degrees and 45 degrees, or between 35 degrees and 45 degrees.

In one example the array of apertures of the mask are uniform in size.

In one example the mask comprises a perimeter wall substantially surrounding the array of apertures, the perimeter wall comprising an opening configured to allow passage therethrough of solder balls corresponding to the size of the apertures.

In one example the mask further comprises a substantially planar plate, the array of apertures defined in the substantially planar plate.

In one example the perimeter wall is coupled to a peripheral region of the substantially planar plate.

In one example the system further comprises a holder comprising a retention region for receiving the electronic package.

In one example the retention region comprises a recess defined in a surface of the holder, the recess configured to receive the electronic package.

In one example the mask and the holder are complementary in shape.

In one example the mask and the holder are configured to be secured in a predetermined relative alignment such that the array of apertures of the mask overlie the retention region of the holder.

In one example the second heater assembly comprises an oven for receiving the electronic package and collectively heating and reflowing the replacement solder balls.

According to another embodiment there is provided an assembly for use in locating a plurality of solder balls onto an array of seats of an electronic package. The assembly comprises a mask, the mask comprising an array of apertures for receiving a respective plurality of solder balls, and a holder, the holder comprising a retention region for receiving the electronic package, the mask configured to be positioned over the holder in a predetermined relative alignment with the holder such that the array of apertures of the mask overlie the retention region of the holder.

In one example the apertures in the array of apertures are uniform in size.

In one example the mask comprises a perimeter wall substantially surrounding the array of apertures, the perimeter wall comprising an opening configured to allow passage therethrough of solder balls corresponding to the size of the apertures.

In one example the mask further comprises a substantially planar plate, the array of apertures defined in the substantially planar plate.

In one example the perimeter wall is coupled to a peripheral region of the substantially planar plate.

In one example the retention region comprises a recess defined in a surface of the holder, the recess configured to receive the electronic package.

In one example the mask and the holder are complementary in shape.

In one example the mask and the holder are configured to be secured to each other once in the predetermined relative alignment.

In one example the assembly further comprises a fixture comprising a cavity dimensioned to receive the holder and the mask overlying the holder.

In one example the cavity of the fixture is complementary in shape and size to a periphery of the mask and/or the holder.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a perspective schematic view of an electronic package having an array of solder balls according to the background art and illustrates one example of a flaw associated with the array of solder balls;

FIGS. 2A to 2D are plan schematic views of an electronic package corresponding generally to the package of FIG. 1, but illustrating various other examples of flaws associated with the array of solder balls;

FIG. 3A illustrates a first example of a method for replacing solder balls of the electronic package of FIG. 1 according to aspects of the present disclosure;

FIG. 3B illustrates a second example of a method for replacing solder balls of the electronic package of FIG. 1 according to aspects of the present disclosure;

FIG. 4 is a perspective schematic view of a fluxing assembly for applying a fluxing agent to the electronic package of FIG. 1 according to aspects of the present disclosure;

FIG. 5 is a schematic view of a syringe sub-assembly and needle sub-assembly of the fluxing assembly of FIG. 4 according to aspects of the present disclosure;

FIGS. 6A and 6B are schematic views of the needle sub-assembly of FIG. 5 in an “as-new” state (FIG. 6A) and in a “deformed state” after the needle has been deformed into an arcuate profile (FIG. 6B);

FIG. 7 is a plan schematic view of the electronic package of FIG. 1 illustrating a step of applying a fluxing agent to the electronic package prior to collectively heating the array of solder balls;

FIGS. 8A and 8B are perspective schematic views of a clamping assembly according to aspects of the present disclosure;

FIG. 9 is a plan schematic view of the clamping assembly of FIGS. 8A and 8B in use to secure the electronic package in a predetermined orientation;

FIG. 10 is a perspective schematic view illustrating a step of mounting the clamping assembly to a hot plate assembly;

FIG. 11 is a schematic view of a solder removal tool for use in removing the solder balls from the electronic package according to aspects of the present disclosure;

FIGS. 12A and 12B are schematic views of a needle of the solder removal tool in an “as new” state (FIG. 12A) and in a “deformed” state after the needle has been deformed into an arcuate profile (FIG. 12B);

FIG. 13 is a plan schematic view of the electronic package after removal of the solder balls;

FIG. 14 is a plan schematic view of the electronic package of FIG. 13 illustrating commencing a step of applying a fluxing agent to the electronic package;

FIG. 15 is a plan schematic view of the electronic package of FIG. 13 after completion of the flux application step illustrated in FIG. 14;

FIG. 16 is a plan schematic view of a holder provided with a recess dimensioned to receive the electronic package;

FIG. 17 is a plan schematic view of a mask having an array of apertures, the mask configured for placement over the holder in a predetermined orientation;

FIG. 18 is a plan schematic view of the mask when mounted over the holder within a surrounding fixture;

FIG. 19 is a view of Region E of FIG. 18, illustrating a single replacement solder ball located in each aperture of the mask so as to be located on a corresponding seat of the electronic package underneath the mask;

FIG. 20 is a perspective schematic view of a reflow oven for receiving the electronic package and reflowing the replacement solder balls; and

FIG. 21 is a perspective schematic view of the electronic package with the reflowed replacement solder balls after removal from the reflow oven.

### DETAILED DESCRIPTION

Aspects and embodiments described herein are directed to a method for replacing solder balls of an electronic package, a system for replacing solder balls of an electronic package, and an assembly for use in locating a plurality of solder balls onto an array of seats of an electronic package. In particular, aspects and embodiments described herein provide for reducing the need to dispose of electronic packages due to flaws associated with the solder balls of the electronic package, thereby reducing costs and wastage of raw materials.

It is to be appreciated that embodiments of the methods and systems discussed herein are not limited in application to the details of construction and the arrangement of components set forth in the following description or illustrated in the accompanying drawings. The method, system and assembly are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

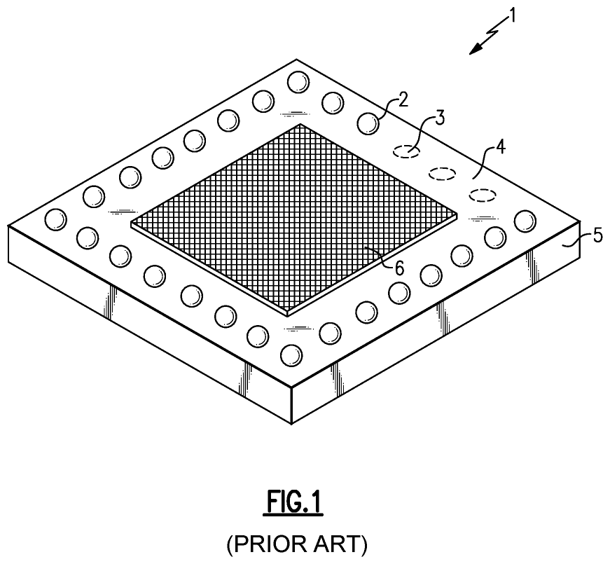

FIG. 1 is a perspective view of an electronic package 1 having an array of solder balls 2 fixed to a corresponding array of seats 3 provided on a surface 4 of a substrate panel 5 of the electronic package. The electronic package 1 may alternatively be referred to as an electronic module. The substrate panel 5 may include a ceramic substrate. The ceramic substrate may include a low temperature co-fired ceramic substrate. However, it will be appreciated that other materials may be used to form the substrate panel 5. The substrate panel 5 may define a printed circuit board. In the embodiment of FIG. 1, the electronic package 1 includes a semiconductor die 6 mounted to the surface 4 of the substrate panel 5. The semiconductor die 6 defines an integrated circuit. However, it will be appreciated that in other examples, one or more electronic components may be mounted to the surface 4 of the substrate panel 5; by way of example, any one or more Surface-Mount Technology (SMT) components may be employed in place of the semiconductor die 6. The seats 3 may be in the form of copper pads, with copper also commonly used to form electrically conductive tracks and interfaces embedded within the structure of the substrate panel 5. However, it will be appreciated that conductive materials other than copper may be used for the seats 3. It will also be appreciated that the seats 3 may be any part of the surface 4 of the electronic package 1 suitable for soldering solder balls thereto. Although not shown in the figures, solder masks may be provided on the surface 4 of the substrate panel 5 surrounding each of the seats 3. FIG. 1 shows the array of solder balls 2 after a reflow operation, with the reflow operation resulting in a metallurgical bond defined between each solder ball 2 and its respective seat 3. However, the electronic package 1 of FIG. 1 has a manufacturing flaw associated with the solder balls 2, with three of the seats 3 missing a respective solder ball.

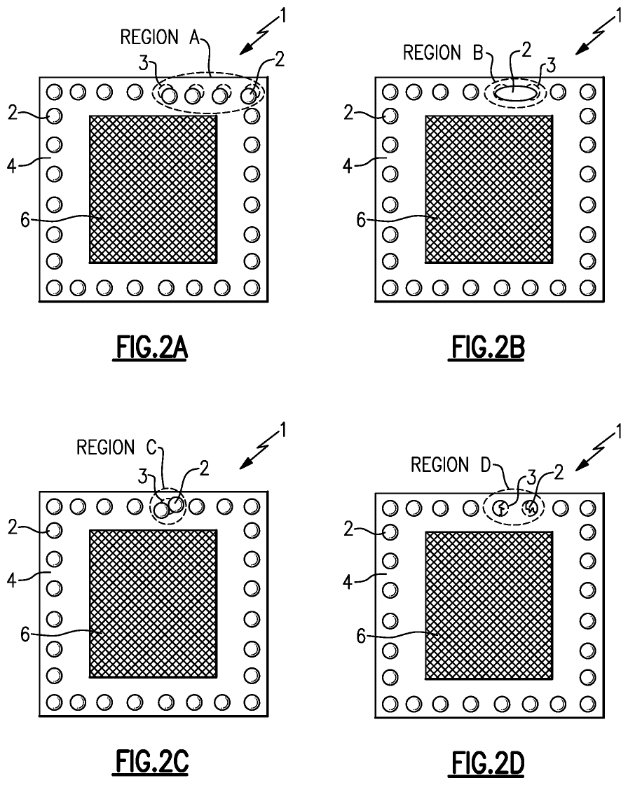

FIGS. 2A to 2D show examples of other possible flaws associated with solder balls 2 of the electronic package 1. FIG. 2A shows four of the solder balls 2 being misaligned on their respective seats 3 (see Region A of FIG. 2A). FIG. 2B shows one or more solder balls 2 bridging two adjacent seats 3 (see Region B of FIG. 2B). FIG. 2C shows two solder balls 2 being positioned on a single seat 3 (see Region C of FIG. 2C). FIG. 2D shows two solder balls 2 having sustained mechanical damage (see Region D of FIG. 2D). Alternatively or in addition, the specification of the solder balls 2 used may be contrary to the design specification for the electronic package 1; for example, solder balls 2 may have been used having a size or formed of a material other than designated in the design specification for the electronic package 1. The nature of the flaws or errors described above may make the electronic package 1 unsuitable for its intended purpose and may require disposal of the electronic package 1, resulting in waste of raw materials and consequent costs.

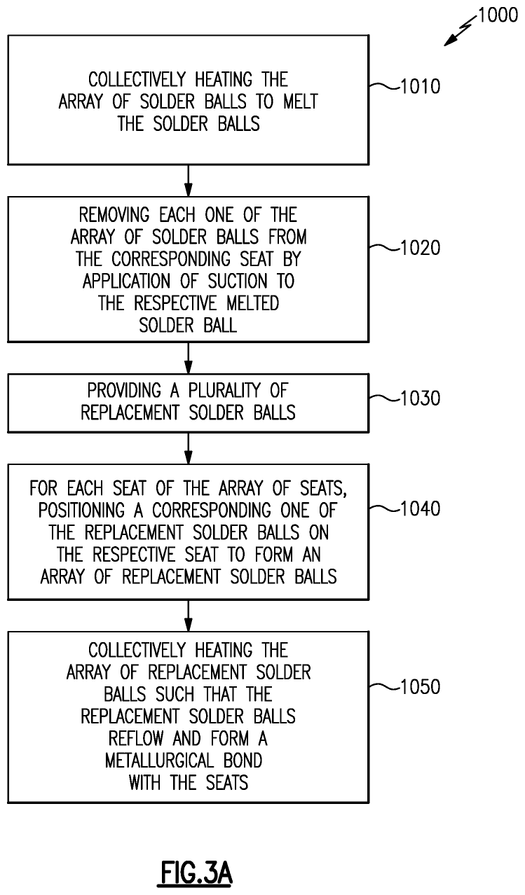

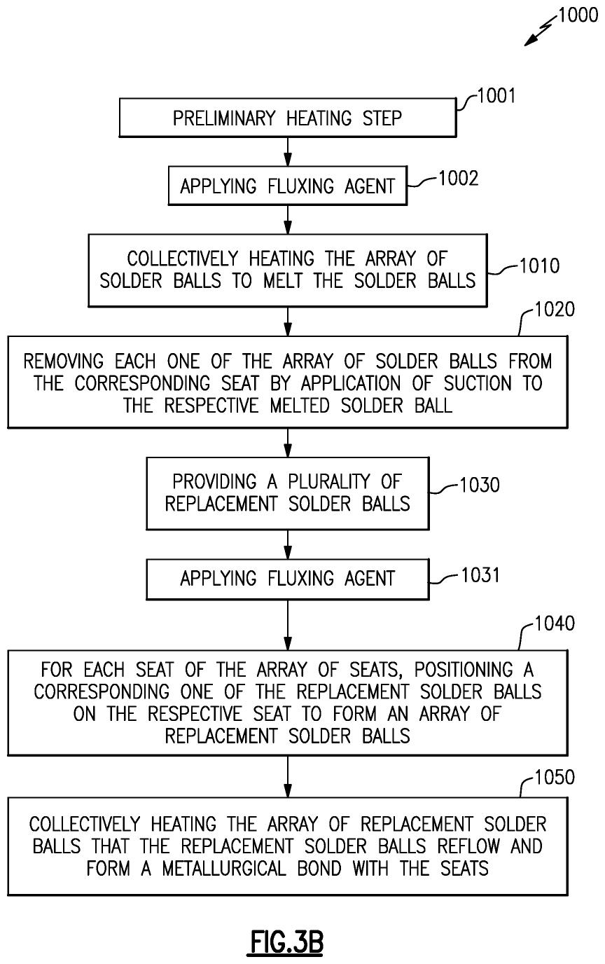

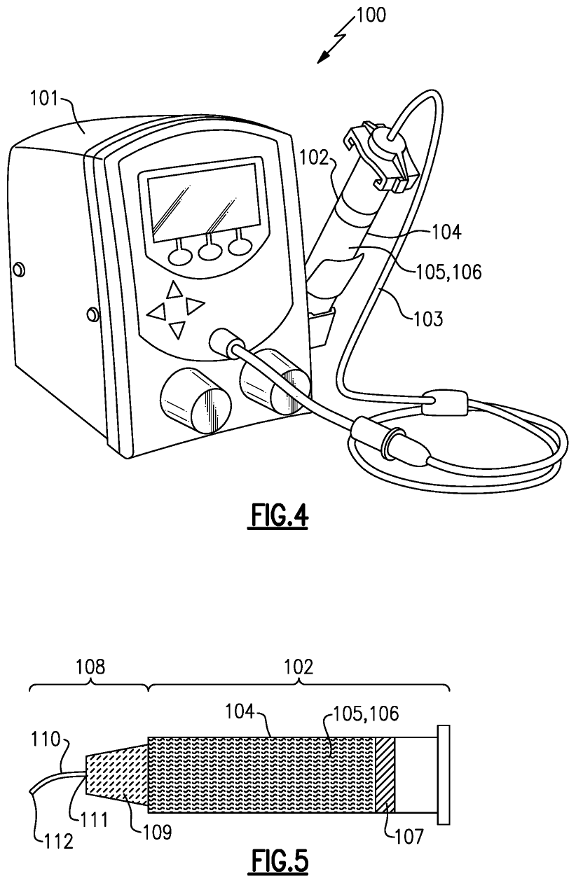

FIG. 3A illustrates a first example of a method 1000 for replacing an array of solder balls of an electronic package. For convenience, the method is described herein by reference to the electronic package 1 shown in FIGS. 1 and 2A to 2D. However, it will be appreciated that the method may be applied to an electronic package 1 differing in one or more aspects from the electronic package 1 of FIGS. 1 and 2A to 2D. For example, although the electronic package 1 of FIGS. 1 and 2A to 2D employs a rectangular array of solder balls 2, in other embodiments the array may be circular, oval or any other shape. Similarly, the method is also suitable for use with a double-sided electronic package in which electronic components and/or dies are mounted to opposing surfaces of the substrate panel. Further, the method 1000 of FIGS. 3A and 3B may also be performed on a variant to the electronic package 1 of FIG. 1, in which a mold structure is provided on the surface 4 of the substrate panel 5 surrounding the die 6 and each of the solder balls 2, to leave the array of solder balls exposed through the mold structure; the mold structure may optionally be an epoxy material.

FIG. 3B illustrates a second example of the method 1000, incorporating additional steps to the method illustrated in FIG. 3A.

The method 1000 of FIG. 3A comprises a step 1010 of collectively heating the array of solder balls 2 to melt the solder balls. The method further comprises a step 1020 of removing each one of the array of solder balls 2 from the corresponding seat 3 by application of suction to the respective melted solder ball. The method further comprises a step 1030 of providing a plurality of replacement solder balls 2′. In a further step 1040, for each of the seats 3, a corresponding one of the replacement solder balls 2′ is positioned on the respective seat 3. Step 1040 results in a single replacement solder ball 2′ being positioned on each of the seats 3 to collectively form an array of the replacement solder balls 2′. In a subsequent step 1050, the array of replacement solder balls 2′ is collectively heated such that the replacement solder balls 2′ reflow and form a metallurgical bond with the respective seats 3. Each of these steps 1010, 1020, 1030, 1040, and 1050 and various other steps are described in more detail below.

The method 1000 of FIGS. 3A and 3B is discussed with reference to the electronic package 1 shown in FIG. 1. For the electronic package 1 of FIG. 1, the surface 4 of the substrate panel 5 (on which the die 6 is mounted) is exposed. Although not visible in the figures, the space between the die 6 and the surface 4 of the substrate panel 5 may be underfilled with a mold material; the mold material may optionally be an epoxy material. However, as indicated above, the method 1000 of FIGS. 3A and 3B may also be performed on a variant to the electronic package 1 of FIG. 1, in which a mold structure is provided on the surface 4 of the substrate panel 5 surrounding the die 6 and each of the solder balls 2, to leave the array of solder balls exposed through the mold structure. The mold structure may optionally be an epoxy material. For this variant to the electronic package 1 of FIG. 1, the method 1000 of FIGS. 3A and 3B may be performed without removal of the mold structure from the surface 4 of the substrate panel 5.

### Preliminary Heating Step

In a variation to the exemplary method 1000 illustrated in FIG. 3A, a preliminary heating step 1001 is performed on the electronic package 1, in which the electronic package is baked at a temperature of at least 110 degrees Celsius, or at least 115 degrees Celsius, or at least 120 degrees Celsius, or at least 125 degrees Celsius for a predetermined minimum time period. This preliminary heating step 1001 is shown in the method 1000 of FIG. 3B. The predetermined minimum time period may be 3.5 hours, or 4 hours, or 4.5 hours. The baking operation 1001 may be performed in an enclosure of an oven to facilitate heating the entirety of the electronic package 1 in a uniform manner. The preliminary heating step 1001 is performed to remove any moisture that may be present on the electronic package 1. The preliminary heating step 1001 may be performed on one or more electronic packages at the same time.

### Application of Fluxing Agent to and Around Existing Solder Balls

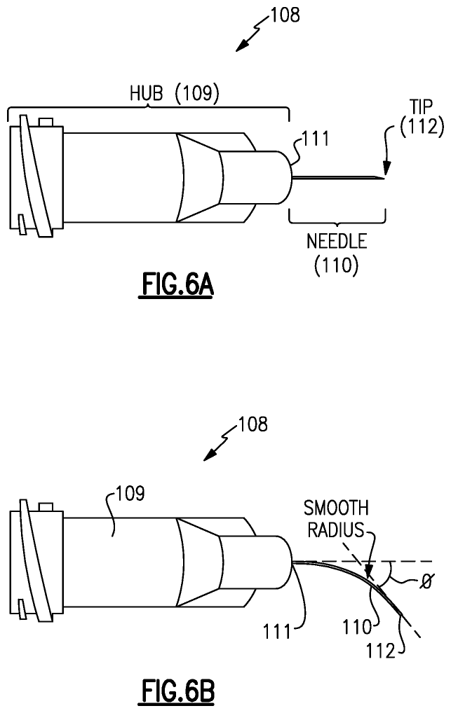

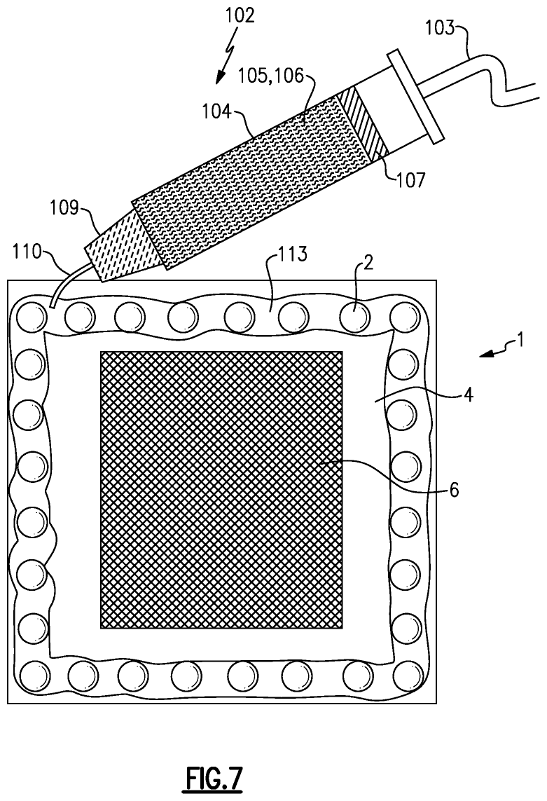

Although not shown in the exemplary method 1000 illustrated in FIG. 3A, in a preferred embodiment the step 1010 of collectively heating the array of solder balls 2 may be preceded by a step of applying a fluxing agent to the surface 4 of the substrate panel 5. This flux application step 1002 is shown in the method 1000 of FIG. 3B. The flux application step 1002 is performed by use of a fluxing assembly, such as the fluxing assembly 100 shown in FIG. 4. The fluxing assembly 100 of FIG. 4 has a flux control unit 101 coupled to a syringe sub-assembly 102 by plastic tubing 103. The syringe sub-assembly 102 is designed to be hand-held by an operator during the flux application step. As shown in FIG. 5, the syringe sub-assembly 102 is in the form of a cartridge 104 containing a reservoir 105 of fluxing agent 106. The fluxing agent 106 is water soluble. The cartridge 104 includes a piston 107. A needle sub-assembly 108 is attached to one end of the syringe sub-assembly 102. As shown in FIGS. 6A and 6B, the needle sub-assembly 108 has a hub 109 and a hollow needle 110. The needle 110 extends from a base 111 to a tip 112, with the base of the needle integrated with one end of the hub 109. The needle 110 is formed of stainless steel or other corrosion resistant metal. The hub 109 is attached to one end of the syringe sub-assembly 102, for example, by means of a screw fit, a bayonet fit, or similar. FIG. 6A shows the needle sub-assembly 108 in an “as-new” state, in which the needle 110 is generally linear between the base 111 and the tip 112. However, it is preferred that the needle 110 be deformed to have a generally arcuate profile as shown in FIG. 6B (and also FIG. 5). It is important to ensure that the hollow needle 110 is not inadvertently crimped when being deformed into the arcuate profile to avoid inadvertently impeding the flow of flux through the needle. The degree of curvature of the arcuate profile can be defined by the magnitude of an acute angle 1 corresponding to the deviation of a tangent to the tip 112 of the needle 110 from a tangent to the base 111 of the needle. It is preferred that this acute angle has a value Φ in a range of between 15 degrees and 45 degrees, or between 25 degrees and 45 degrees, or between 35 degrees and 45 degrees. Prior to commencement of applying the fluxing agent 106 to the surface 4 of the substrate panel 5, it is preferred that the operator purges the needle 110 of any air contained within the needle. This purging step may help to reduce the likelihood of air bubbles being introduced into fluxing agent 106 dispensed from the needle 110.

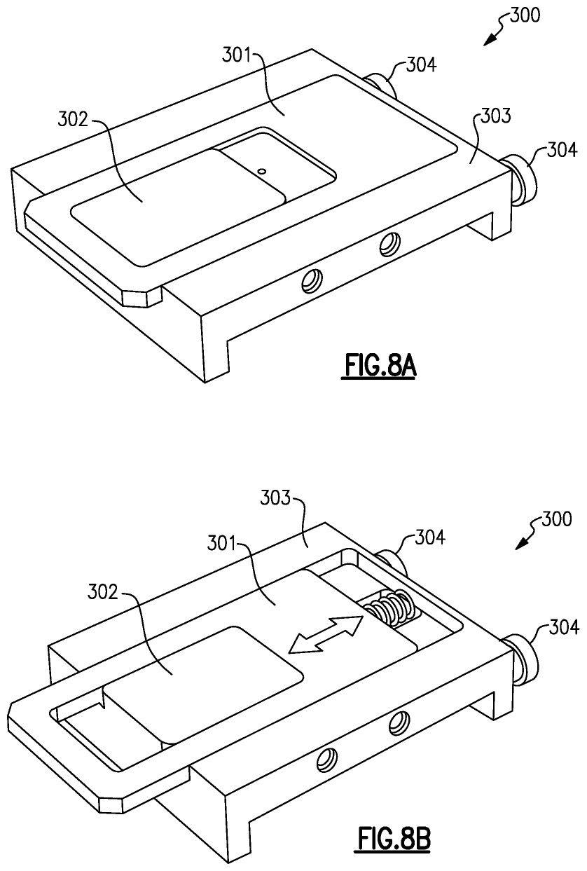

During the flux application step 1002, an operator inclines the syringe sub-assembly 102 at an acute angle relative to the generally planar surface 4 and carefully applies fluxing agent 106 via the tip 112 of the arcuate needle 110 to the surface so as to form a continuous path 113 of the fluxing agent 106. The flux control unit 101 controls a supply of pressurized air through the plastic tubing 103 to cause the piston 107 to urge fluxing agent 106 out from the cartridge 104 via the tip 112 of the needle 110. The operator ensures that the surface of each of the solder balls 2 is covered with fluxing agent 106. As shown in FIG. 7, the continuous line 113 of fluxing agent 106 covers each of the solder balls 2 and portions of the surface 4 separating adjacent ones of the solder balls 2. Where the method is performed on a variant to the electronic package 1 in which a mold structure is provided on the surface 4 of the substrate panel 5 surrounding the die 6 and each of the solder balls 2 to leave the array of solder balls exposed through the mold structure, the flux application step 1002 would be performed so that the continuous path 113 of fluxing agent 106 would cover each of the solder balls 2 and portions of the mold structure separating adjacent ones of the solder balls.

### Melting the Existing Solder Balls

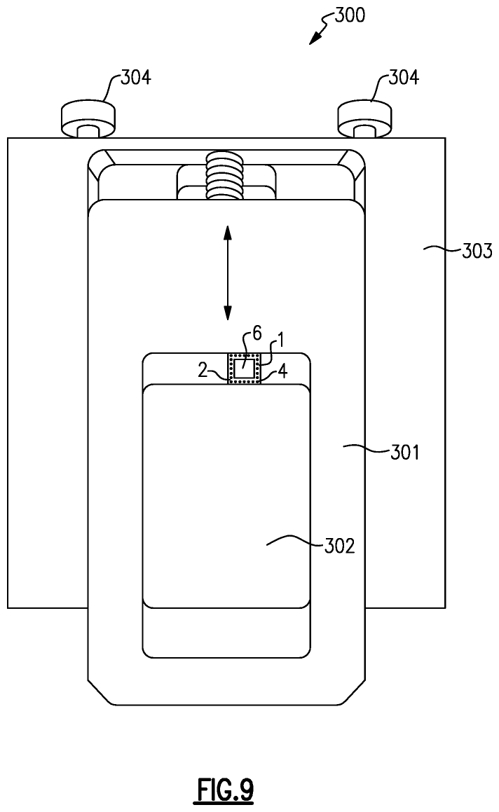

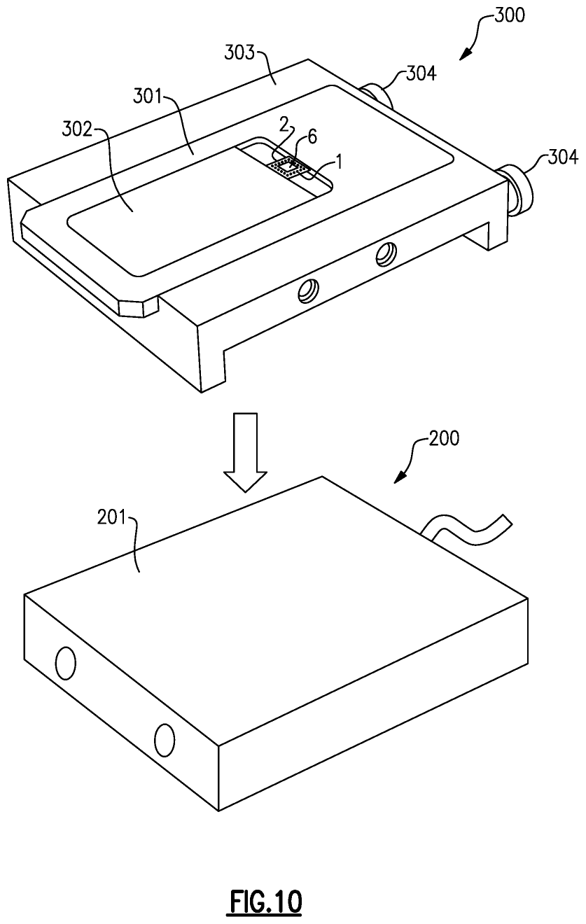

The step 1010 of collectively heating the array of solder balls 2 to melt the solder balls is performed using a first heater assembly, such as an electrically powered hot plate assembly 200 as shown in FIG. 10. The electronic package 1 is not directly placed onto the surface 201 of the hot plate assembly 200. Rather, the electronic package 1 is initially secured in a clamping assembly 300, with the clamping assembly mounted to the hot plate assembly 200. As shown in FIGS. 8A, 8B, 9, and 10, the clamping assembly 300 has outer and inner clamping elements 301, 302 mounted within a support body 303. The outer clamping element 301 surrounds the inner clamping element 302, with the outer clamping element slidably mounted to the support body 303 so as to be slidable relative to the inner clamping element. As shown by the arrow in FIGS. 8B and 9, the outer clamping element 301 is slidably moveable relative to the inner clamping element 302 so that opposed edges of the electronic package 1 are clamped by corresponding edges of the outer clamping element and the inner clamping element. The clamping assembly 300 of FIGS. 8A, 8B, 9, and 10 is formed of steel. However, it will be appreciated that the clamping assembly 300 may instead be formed from any material having sufficient strength to clamp the electronic package 1 and having a melting point higher than that of the solder balls 2.

The electronic package 1 is oriented in the clamping assembly 300 so that surface 4 and the array of solder balls 2 are exposed in line of sight of the operator. The electronic package 1 is secured in the clamping assembly 300 away from the hot plate assembly 200. The hot plate assembly 200 is pre-heated to a predetermined temperature prior to the clamping assembly 300 being mounted to the hot plate assembly. The clamping assembly 300 (in which the electronic package 1 is secured) is then mounted to the pre-heated hot plate assembly 200. The clamping assembly 300 additionally includes one or more knurled bolts 304 which can be adjusted to engage with corresponding holes formed in a side face of the hot plate assembly 200, thereby allowing the clamping assembly to be securely mounted to the hot plate assembly. In use, heat transfers from the hot plate assembly 200 to the electronic package 1 and each of the solder balls 2 by means of conduction (via the clamping assembly 300 and through the electronic package 1) and radiation (from the surface 201 of the hot plate assembly 200). The specific value of the predetermined temperature of the hot plate assembly 200 will be chosen dependent on the melting point of the material of the solder balls 2. The predetermined temperature should be sufficient such that the solder balls 2 attain a molten state. By way of example, where the solder balls 2 are formed of material having a melting point of around 240° C., the predetermined temperature of the hot plate assembly 200 may be around 260° C. It will be appreciated that the predetermined temperature used for the hot plate assembly 200 will be dependent on factors such as the material used for the solder balls 2, the material used for the clamping assembly 300 and the distance by which the electronic package 1 is separated from the surface 201 of the hot plate assembly.

### Removal of the Existing Solder Balls

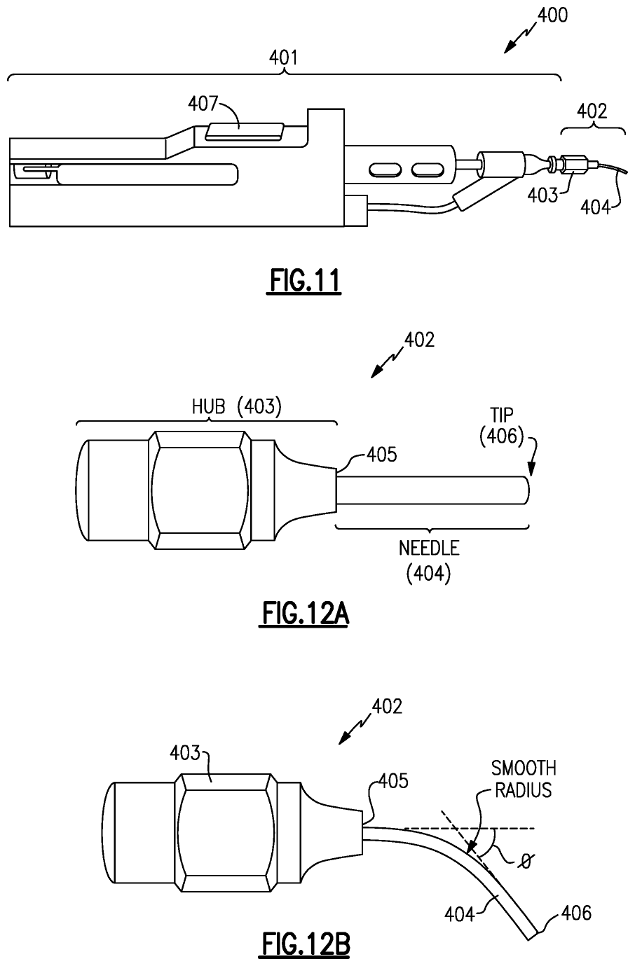

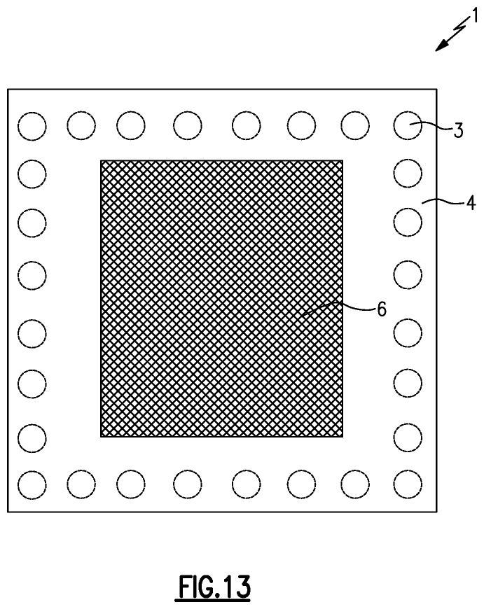

Once the solder balls 2 have attained a molten state, a solder removal tool 400 is employed to remove the melted solder balls from their corresponding seats 3 by use of suction in accordance with step 1020 of the method 1000 of FIG. 3A. FIG. 11 shows an exemplary solder removal tool 400 having an elongate body 401 and a needle sub-assembly 402 coupled to one end of the body. The needle sub-assembly 402 has a hub 403 and a needle 404. The hub 403 is adapted for connection to the end of the elongate body 401 by a screw-fit, a bayonet-fit, or similar. The needle 404 extends from a base 405 to a tip 406. The base 405 of the needle 404 is integrated with the hub 403. The needle sub-assembly 402 is formed of metal such as stainless steel, however, it will be appreciated that other metals may be used having a melting point well above that of the material of the solder balls 2. The elongate body 401 contains a motor assembly configured to generate suction at the tip 406 of the hollow needle 404 and a collection chamber for receiving melted solder balls conveyed through the needle sub-assembly 402. A button 407 is provided on the outside of the elongate body 401 and is operatively coupled to the motor assembly to trigger the generation of suction through the needle 404 only for as long as the button is depressed. The elongate body 401 also contains a heater configured to heat the needle sub-assembly 402 to a temperature corresponding to at least the melting point of the material of the solder balls 2. FIG. 12A shows the needle sub-assembly 402 in an “as-new” state, in which the needle 404 is generally linear. However, in common with the fluxing assembly 100, it is preferred that, prior to use of the solder removal tool 400, the needle 404 is deformed to have a generally arcuate profile as shown in FIG. 12B. It is important to ensure that the needle 404 is not inadvertently crimped when being deformed into the arcuate profile to avoid inadvertently impeding suction through the hollow needle. The degree of curvature of the arcuate profile can be defined by the magnitude of an acute angle Φ corresponding to the deviation of a tangent to the tip 406 of the needle 404 from a tangent to the base 405 of the needle. It is preferred that this acute angle has a value Φ in a range of between 15 degrees and 45 degrees, or between 25 degrees and 45 degrees, or between 35 degrees and 45 degrees.

With the electronic package 1 secured in the clamping assembly 300 and the clamping assembly secured to the hot plate assembly 200, the operator holds the elongate body 401 to incline the solder removal tool 400 at an acute angle relative to the surface 4 and carefully positions the tip 406 of the heated needle 404 above one of the molten solder balls 2. The operator then presses button 407 to apply suction through the heated hollow needle 404. The suction at the tip 406 of the needle 404 causes the molten solder ball 2 to be sucked from its seat 3 and pass along through the needle to be received inside the collection chamber housed within the interior of the elongate body 401. The operator repeats this process for each of the molten solder balls 2 until all of the solder balls have been removed from their corresponding seats 3. Additional fluxing agent 106 may be applied to the surface 4 during step 1020 if the fluxing agent previously applied appears insufficient and/or has dried out.

FIG. 13 shows the surface 4 of the electronic package 1 after removal of all of the molten solder balls 2, showing the now exposed seats 3 to which the solder balls had previously been fixed. The clamping assembly 300 is removed from the hot plate assembly 200 and the electronic package 1 allowed to cool. Once the electronic package 1 has cooled down to room temperature, the operator then wipes the surface 4 with a solution of isopropyl alcohol or similar cleaning agent to remove residual flux and/or other residues which remain after the step 1020 of removing the solder balls 2.

Where the electronic package 1 has a mold structure provided on the surface 4 of the substrate panel 5 surrounding the die 6 and each of the solder balls 2, to leave the array of solder balls exposed through the mold structure, the step 1020 of removing the molten solder balls 2 may be performed using the solder removal tool 400 described above. In this molded variant to the electronic package 1, removal of all of the molten solder balls 2 would leave the seats 3 exposed through the mold structure.

### Replacement Solder Balls

The operator provides a plurality of replacement solder balls 2′, in accordance with step 1030 of the method 1000 of FIG. 3A. It will be appreciated that the size and material specifications for the replacement solder balls 2′ will be chosen based on the intended use of the electronic package 1 and the assembly to which the electronic package is intended to be coupled (for example, a circuit board of an electronic device). The size and material specifications of the replacement solder balls 2′ may be identical to or differ from those of the solder balls 2 previously removed from the surface 4 of the electronic package 1. By way of example and without limitation, the replacement solder balls 2′ and/or the old solder balls 2 may have a nominal diameter of 220 micrometers, 240 micrometers, 250 micrometers, or 280 micrometers. In the illustrated embodiment, the plurality of replacement solder balls 2′ have a uniform diameter.

### Application of Fluxing Agent and Positioning of Replacement Solder Balls on the Electronic Package

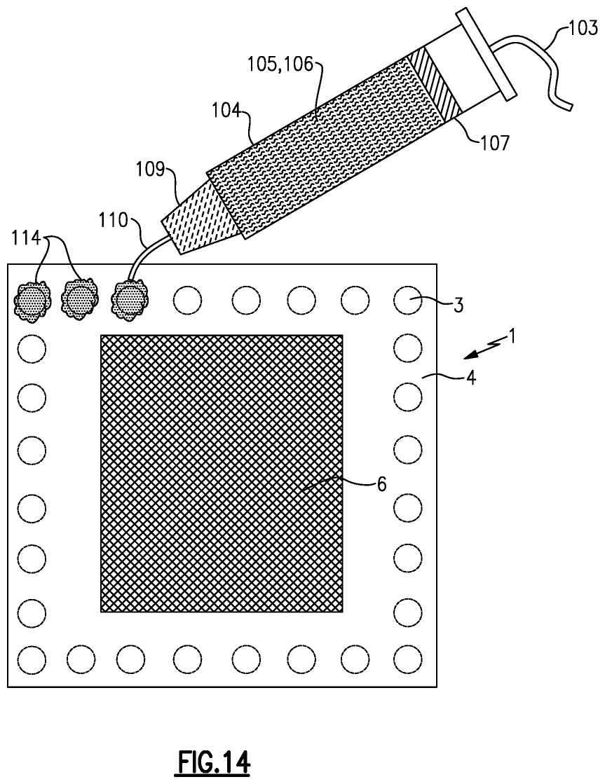

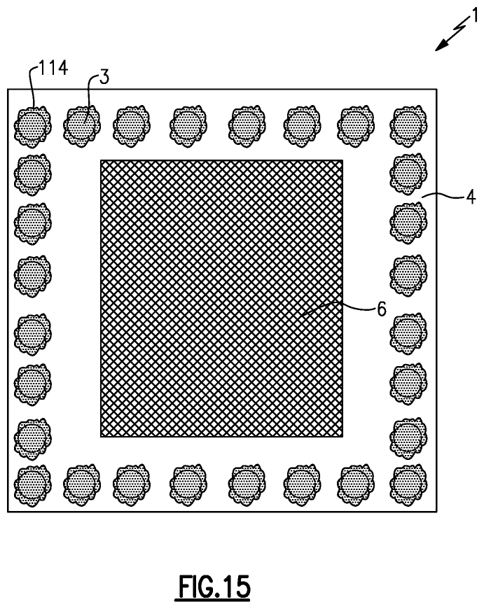

For each seat 3, a single one of the plurality of replacement solder balls 2′ is positioned on the respective seat, in accordance with step 1040. Although not shown in the method 1000 of FIG. 3A, step 1040 is preferably preceded by a step of applying a fluxing agent to the electronic package 1. This flux application step 1031 is shown in the method 1000 of FIG. 3B. The flux application step 1031 is performed by use of a fluxing assembly, such as the fluxing assembly 100 generally shown in FIG. 4 and discussed above in relation to FIGS. 5, 6A, and 6B. The same fluxing agent 106 may be used as described above. As previously described, prior to commencement of applying the fluxing agent 106 to the electronic package 1, it is preferred that the operator purges the needle 110 of any air contained within the needle. This purging step may help to reduce the likelihood of air bubbles being introduced into fluxing agent 106 dispensed from the needle 110. During the flux application step 1031, the operator inclines the syringe sub-assembly 102 at an acute angle relative to the surface 4 and carefully applies discrete portions 114 of fluxing agent 106 via the tip 112 of the arcuate needle 110 to each of the exposed seats 3 so that the fluxing agent does not bridge adjacent ones of the seats—as shown in FIGS. 14 and 15. This flux application step 1031 may be performed with the electronic package 1 still secured in the clamping assembly 300.

Where the electronic package 1 has a mold structure provided on the surface 4 of the substrate panel 5 surrounding the die 6 and each of the solder balls 2, to leave the array of solder balls exposed through the mold structure, the flux application step 1031 may be performed as described above, with fluxing agent 106 confined to each of the exposed seats 3.

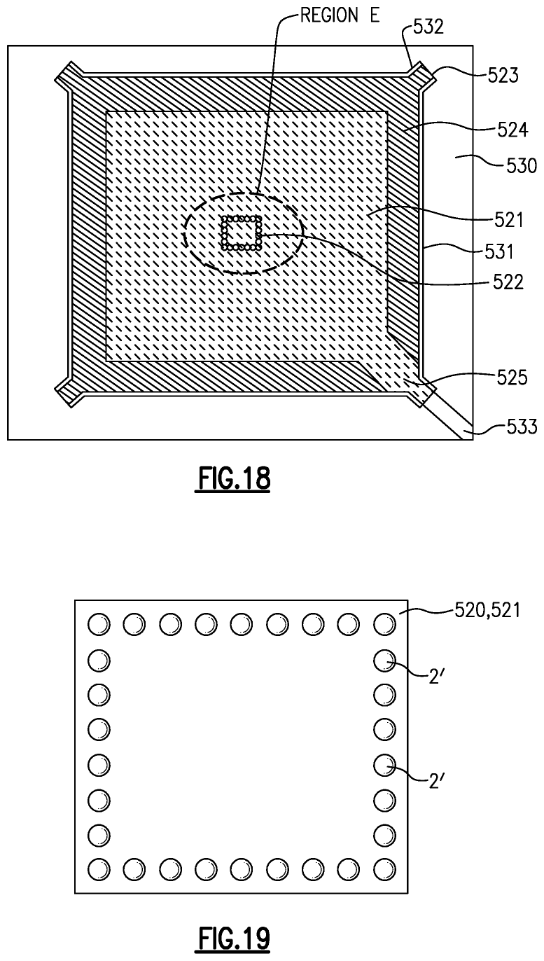

Once the flux application step 1031 described above has been completed, step 1040 may be undertaken. To assist in accurate positioning of each replacement solder ball 2′ on a corresponding one of the seats 3, a combination of a holder 510 and a mask 520 is provided. As shown in FIG. 16, the holder 510 is generally in the form of a square or rectangular steel plate 511, with a recess 512 defined in a central region of the plate. The recess 512 is dimensioned to receive the electronic package 1 while also substantially preventing lateral movement of the electronic package within the recess. Lugs 513 extend diagonally from each corner of the plate 511. The electronic package 1, with portions 114 of fluxing agent 106 located on each of the exposed seats 3, is seated within the recess 512 of the holder 510 so that the fluxed seats face upwardly. The holder 510 is then positioned within a square blind cavity 531 of a fixture 530 (FIG. 18), with the cavity 531 dimensioned to be substantially complementary in shape to the periphery of the holder. The lugs 513 of the holder 510 locate in corresponding recesses 532 defined in corners of the cavity 531 of the fixture 530. The fixture 530 is made from steel or another suitable material having a melting point higher than that of the solder balls 2′.

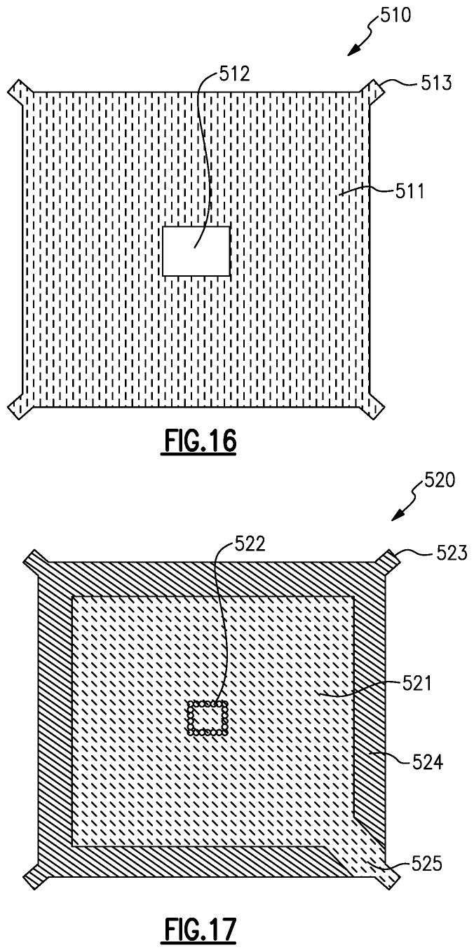

As shown in FIG. 17, the mask 520 has a complementary shape to the holder 510. The mask 520 is formed of a square or rectangular plate 521, with an array of apertures 522 provided in a central region of the plate. The array of apertures 522 are uniform in size. Each of the array of apertures 522 is sized so as to only be able to receive a single one of the plurality of replacement solder balls 2′. Lugs 523 extend diagonally from each corner of the plate 521. The mask 520 also includes a perimeter wall 524 coupled to a periphery of the plate 521. An opening 525 is provided in the perimeter wall 524 at one corner of the mask 520. The mask 520 is placed over the holder 510 within the cavity 531 of the fixture 530 so that the lugs 523 locate in the corresponding recesses 532 of the fixture 530; the lugs 523 of the mask 520 overlie the lugs 513 of the holder 510.

The array of apertures 522 in the plate 521 of the mask 520 are arranged to correspond precisely with the spatial disposition of the array of seats 3 of the electronic package 1. So, when the mask 520 is placed over the holder 510 as shown in FIG. 18, the array of apertures 522 of the mask 520 align with the array of fluxed seats 3 of the electronic package 1 retained in the recess 512 of the holder 510. Once the mask 520 and holder 510 are so aligned, the mask is secured to the holder using a latching mechanism or similar. The operator would then pour the plurality of replacement solder balls 2′ onto the plate 521 of the mask 520 and gently shake the fixture 530 from side to side until a single replacement solder ball 2′ is received within each aperture 522 and located on a corresponding one of the fluxed seats 3 of the electronic package 1 underneath the mask; this is illustrated in FIG. 19, which shows a detail view of Region E of the plate 521 of the mask 520. Where the electronic package 1 has a mold structure provided on the surface 4 of the substrate panel 5 surrounding the die 6 and each of the solder balls 2, to leave the array of solder balls exposed through the mold structure, the mold structure which surrounds each of the seats 3 may facilitate locating each of the replacement solder balls 2 on a corresponding one of the fluxed seats 3.

The perimeter wall 524 of the mask 520 facilitates containing the replacement solder balls 2′ on the plate 521 when the fixture 530 is shaken from side to side. Once each of the apertures 522 contains a single one of the replacement solder balls 2′, the fixture 530 is inclined to pour any excess solder balls through the opening 525 in the perimeter wall and a corresponding opening or funnel 533 defined in the fixture. The apertures 522 in the plate 521 of the mask 520 are dimensioned according to the size of the replacement solder balls 2′. More specifically, the apertures 522 are sized to be slightly larger than the diameter of the replacement solder balls 2′ while also ensuring that each replacement solder ball remains generally centrally located on its corresponding fluxed seat 3. To ensure that the replacement solder balls 2′ are able to form a satisfactory soldered connection only with the seats 3 of the electronic package 1, it is beneficial to ensure that both the replacement solder balls 2′ and the surfaces of the holder 510 and the mask 520 are free of grease, oil, or other potential contaminants. The holder 510 and mask 520 are formed from steel, however, it will be appreciated that other materials may be used which have a melting point higher than that of the material of the replacement solder balls 2′. The holder 510 and mask 520 shown in the figures are 27 millimeters square. However, it will be appreciated that the mask 520 and the holder 510 may be of any suitable size sufficient to receive the electronic package 1.

### Reflow of Replacement Solder Balls

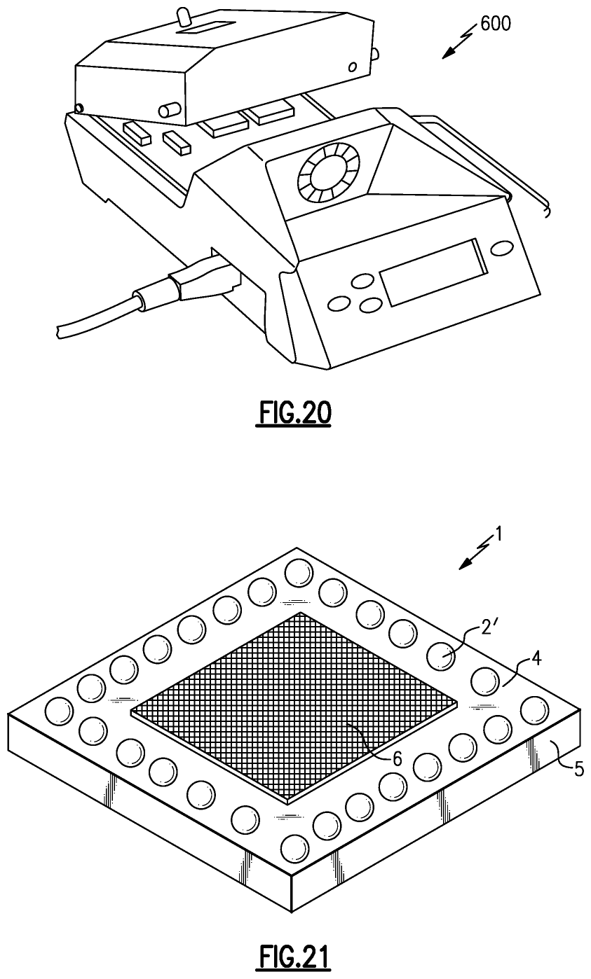

For step 1050 of the method 1000 of FIG. 3A, the fixture assembly 530 retaining the holder 510 and mask 520 is then placed in a reflow oven 600 (see FIG. 20) which has been pre-heated to a temperature sufficient to cause reflow of the replacement solder balls 2′ and their attachment to the seats 3. The reflow oven 600 collectively heats the array of replacement solder balls 2′ to reflow the solder material. Reflow of the solder material results in a metallurgical bond being formed between each replacement solder ball 2′ and the corresponding seat 3. By way of example, the reflow oven 600 may be set by a user to employ a soak temperature of 171° C. to be held for a duration of 35 seconds, and a peak reflow temperature of 245° C. and a reflow duration of 80 seconds. For the embodiment illustrated in the figures, the reflow oven 600 processes a single electronic package 1 at a time.

After removal from the reflow oven, the electronic package 1 complete with its array of replacement solder balls 2′ fixed in place on the seats 3 is allowed to cool. FIG. 21 shows the electronic package 1 with the array of replacement solder balls 2′ correctly arranged on the corresponding seat 3 according to the design specification for the package.

Once the electronic package 1 has cooled down after removal from the reflow oven 600, the operator may apply a cleaning agent to the surface 4 of the electronic package 1 and the replacement solder balls 2′ to remove any residue remaining after the fluxing and reflow steps. The cleaning agent may be isopropyl alcohol or similar. In a subsequent step, the cleaned electronic package 1 may also be placed within the enclosure of an oven and baked to remove any residual moisture remaining on the electronic package.

The resulting electronic package 1 of the present disclosure (for example, the electronic package 1 of FIG. 21) may be incorporated in an electronic device, such as a wireless device. By way of example and without limitation, such a wireless device can include, for example, a cellular phone, a smart-phone, a hand-held wireless device with or without phone functionality, a wireless tablet, a wireless router, a wireless access point, a wireless base station, etc. However, it will be appreciated that the electronic package of the present disclosure is not limited to incorporation in wireless devices.

It will be noted that the figures are for illustrative purposes only, and are not to scale.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method for replacing solder balls of an electronic package, the electronic package comprising an array of solder balls soldered to a corresponding array of seats located on a surface of the electronic package, the method comprising:
collectively heating the array of solder balls to melt the solder balls;
removing each one of the array of solder balls from the corresponding seat by application of suction to the melted solder balls;
providing a plurality of replacement solder balls;
for each seat of the array of seats, positioning a corresponding one of the replacement solder balls on the respective seat to form an array of seated replacement solder balls; and
collectively heating the array of seated replacement solder balls such that the replacement solder balls reflow and form a metallurgical bond with the seats.

2. The method of claim 1 wherein collectively heating the array of solder balls is preceded by a preliminary heating step, the preliminary heating step comprising baking the electronic package for a predetermined minimum time period of at least one of 3.5 hours, 4 hours, or 4.5 hours at a temperature of one of at least 110 degrees Celsius, at least 115 degrees Celsius, at least 120 degrees Celsius, or at least 125 degrees Celsius.

3. The method of claim 1 wherein collectively heating the array of solder balls to melt the solder balls is preceded by applying a water soluble fluxing agent to the electronic package such that the fluxing agent covers the solder balls.

4. The method of claim 3 wherein applying the fluxing agent to the electronic package comprises confining application of the fluxing agent to cover the solder balls and portions of the electronic package separating adjacent ones of the solder balls.

5. The method of claim 3 wherein applying the fluxing agent to the electronic package comprises applying the fluxing agent to the electronic package so as to form a continuous path of the fluxing agent covering each of the solder balls.

6. The method of claim 3 wherein applying the fluxing agent to the electronic package comprises dispensing the fluxing agent through a hollow needle coupled to a reservoir of the fluxing agent preceded by a purging step, the purging step comprising purging the hollow needle of air such that fluxing agent dispensed from the hollow needle is free of air bubbles.

7. The method of claim 3 further comprising dispensing additional fluxing agent to either or both of the solder balls and portions of the electronic package separating adjacent ones of the solder balls during either or both of the steps of collectively heating the array of solder balls to melt the solder balls, or removing each one of the array of solder balls from the corresponding seat by application of suction to the respective melted solder ball.

8. The method of claim 1 wherein collectively heating the array of solder balls to melt the solder balls comprises mounting the electronic package to a first heater assembly including a hot plate by providing a clamping assembly, using the clamping assembly to clamp and retain the electronic package in a predetermined orientation, and mounting the clamping assembly to the first heater assembly in which the array of solder balls is exposed in line of sight.

9. The method of claim 8 wherein collectively heating the array of solder balls to melt the solder balls comprises heating the first heater assembly to a predetermined temperature that exceeds a melting temperature of the solder balls by a temperature differential of one of between 10° C. and 40° C., between 10° C. and 30° C., or between 10° C. and 20° C.

10. The method of claim 9 wherein the first heater assembly is pre-heated to the predetermined temperature prior to the electronic package being mounted to the first heater assembly and the first heater assembly is maintained at the predetermined temperature throughout the step of collectively heating the array of solder balls to melt the solder balls.

11. The method of claim 8 wherein removing each one of the array of solder balls from the corresponding seat by application of suction to the melted solder balls is performed while the electronic package is mounted to the first heater assembly.

12. The method of claim 1 wherein removing each one of the array of solder balls from the corresponding seat by application of suction to the melted solder balls comprises providing a hollow needle coupled to a suction source, and positioning the hollow needle over the melted solder ball such that the suction source applies suction via the hollow needle to suck the melted solder ball through the hollow needle.

13. The method of claim 12 wherein removing each one of the array of solder balls from the corresponding seat by application of suction to the respective melted solder ball further comprises heating the needle to at least the melting temperature of the solder balls.

14. The method of claim 1 wherein removing each one of the array of solder balls from the corresponding seat by application of suction to the respective melted solder ball comprises successively removing each of the melted solder balls in turn.

15. The method of claim 1 wherein removing each one of the array of solder balls from the corresponding seat is followed by applying a cleaning agent including isopropyl alcohol to the electronic package.

16. The method of claim 1 wherein positioning the corresponding one of the replacement solder balls on the respective seat is preceded by applying a fluxing agent through a hollow needle coupled to a reservoir of the fluxing agent to the array of seats of the electronic package such that the fluxing agent does not bridge adjacent ones of the seats, applying the fluxing agent to the array of seats being preceded by a purging step including purging the hollow needle of air such that fluxing agent dispensed from the needle is free of air bubbles.

17. The method of claim 1 wherein positioning the corresponding one of the replacement solder balls on the respective seat to form an array of seated replacement solder balls comprises providing a mask, the mask including an array of apertures arranged to correspond to the array of seats, each aperture of the array of apertures sized to receive only a single one of the plurality of replacement solder balls, positioning the mask over the electronic package such that the array of apertures are aligned with the array of seats, disposing one of the plurality of replacement solder balls in a corresponding one of the array of apertures such that the replacement solder ball is located on a corresponding one of the array of seats, and repeating disposing one of the plurality of replacement solder balls in the corresponding one of the array of apertures until each aperture in the array of apertures has received a corresponding one of the plurality of replacement solder balls.

18. The method of claim 1 wherein the plurality of replacement solder balls each have a diameter in a range of 220 micrometers to 280 micrometers.

19. The method of claim 17 wherein the mask comprises a perimeter wall substantially surrounding the array of apertures, and disposing one of the plurality of replacement solder balls in a corresponding one of the array of apertures comprises disposing the plurality of replacement solder balls on a surface of the mask inwards of the perimeter wall, and inclining the mask such that the plurality of replacement solder balls roll over the surface of the mask until each one of the array of apertures receives a corresponding one of the plurality of replacement solder balls and, the perimeter wall substantially confining the plurality of replacement solder balls to inwards of the perimeter wall.

20. The method of claim 19 further comprising inclining the mask to pour excess ones of the plurality of replacement solder balls from the surface of the mask through an opening defined in the perimeter wall.
